(19) United States
(12) Patent Application Publication
(10) Pub. No.: US 2010/0301364 A1
(43) Pub. Date: Dec. 2, 2010

(54) LIGHT EMISSION DEVICE

(76) Inventors: Dong-Su Chang, Suwon-si (KR); Kyung-Sun Ryu, Suwon-si (KR); Jae-Young Lee, Suwon-si (KR)

Correspondence Address: CHRISTIE, PARKER & HALE, LLP, PO BOX 7068, PASADENA, CA, 91109-7068, US

(21) Appl. No.: 12/780,534

(22) Filed: May 14, 2010

(30) Foreign Application Priority Data
May 26, 2009 (KR) 10-2009-0046035

(51) Int. Cl. H01L 33/02; H01L 33/36; H01L 33/44

(52) U.S. Cl. 257/98; 257/E33.002; 257/E33.061; 257/E33.062

(57) ABSTRACT

A light emission device and a display device including the same. The light emission device includes: a substrate body having a concave portion recessed into the substrate body and extending along a first direction; a first electrode in the concave portion and extending along the first direction; a second electrode on a front surface of the substrate body and extending along a second direction crossing the first electrode; an anti-conduction electrode disposed at an edge portion of the substrate body and extending along the second direction to be parallel with the second electrode; and an electron emission unit on the first electrode and spaced apart from the second electrode. Here, each of the second electrode and the anti-conduction electrode includes: a mesh unit having a plurality of opening portions; and a support unit joined to the substrate body while surrounding the mesh unit.

### CROSS-REFERENCE TO RELATED APPLICATION

This application claims priority to and the benefit of Korean Patent Application No. 10-2009-0046035, filed in the Korean Intellectual Property Office on May 26, 2009, the entire content of which is incorporated herein by reference.

### BACKGROUND

1. Field

The following description relates generally to a light emission device and a display device using the same, and more particularly, to a light emission device using a field emission effect and a display device using the same.

2. Description of the Related Art

A light emission device for emitting light may be a light emission device using a field emission effect. A light emission device using the field emission effect may include a front substrate formed with a phosphor layer (or a fluorescent layer) and an anode electrode thereon, and a rear substrate formed with an electron emission unit and driving electrodes thereon. Here, edges (or edge portions) of the front substrate and the rear substrate are integrally joined to each other by a sealing member, and an inner space is evacuated to form a vacuum container (vacuum chamber) together with the sealing member.

In one embodiment, the driving electrodes include a cathode electrode and a gate electrode spaced apart from the cathode electrode and extending in a direction crossing the cathode electrode. In addition, an opening is formed on the gate electrode at a crossing region of the cathode electrode and the gate electrode, and the electron emission unit (electron emission region) is disposed on the cathode electrode to be spaced apart from the gate electrode.

By this configuration, when a set or predetermined driving voltage is applied to the cathode electrode and the gate electrode, an electric field is formed around the electron emission unit by a difference in voltage between the two electrodes to emit electrons from the electron emission unit. The emitted electrons collide with the phosphor layer by being induced by high voltage applied to the anode electrode to excite the phosphor layer, such that the phosphor layer emits visible light.

However, when the set or predetermined driving voltage is applied to the cathode electrode and the gate electrode, unnecessary charging of electric charges may be charged or generated between the gate electrode and another gate electrode, between the cathode electrode and the gate electrode, between the gate electrode and the anode electrode, and the like. This unnecessary charging of electric charges may cause an arc discharge that may damage the electron emission unit and the electrodes.

The above information disclosed in this Background section is only for enhancement of understanding of the background of the described technology and therefore it may contain information that does not form the prior art that is already known in this country to a person of ordinary skill in the art.

### SUMMARY OF THE INVENTION

Aspects of embodiments of the present invention are directed toward a light emission device capable of reducing or minimizing manufacturing errors while suppressing unnecessary electrification by improving its structure, and a display device using the same.

An exemplary embodiment provides a light emission device that includes: a substrate body having a concave portion recessed into the substrate body and extending along a first direction; a first electrode in the concave portion and extending along the first direction; a second electrode on a front surface of the substrate body and extending along a second direction crossing the first electrode; an anti-conduction electrode disposed at an edge portion of the substrate body and extending along the second direction to be parallel with the second electrode; and an electron emission unit on the first electrode and spaced apart from the second electrode. Here, each of the second electrode and the anti-conduction electrode includes: a mesh unit having a plurality of opening portions; and a support unit joined to the substrate body while surrounding the mesh unit.

In one embodiment, the substrate body is divided into a light emission area corresponding to where the electron emission unit emits electrons and a non-emission area adjacent to the light emission area, the second electrode is disposed in the light emission area of the substrate body, and the anti-conduction electrode is disposed in the non-emission area of the substrate body. Here, the anti-conduction electrode may be grounded. Also, each of the second electrode and the anti-conduction electrode may have a thickness larger than that of the first electrode, and may be formed of a metal plate composed of identical material.

In one embodiment, the mesh unit of the second electrode is formed only at a region of the second electrode crossing the first electrode.

In one embodiment, the mesh unit of the second electrode is formed both at a region of the second electrode crossing the first electrode, and a region of the second electrode between the region of the second electrode crossing the first electrode and another region of the second electrode crossing another first electrode.

In one embodiment, the mesh unit of the anti-conduction electrode is formed with identical pattern as the mesh unit of the second electrode.

In one embodiment, the concave portion has a width larger than that of the first electrode, and the concave portion has a recession depth larger than a sum of a thickness of the first electrode and a thickness of the electron emission unit.

In one embodiment, the light emission device further includes: an additional substrate body facing the substrate body; and a third electrode and a phosphor layer on a surface of the additional substrate body facing the substrate body.

Another embodiment provides a display device that includes the light emission device according to the above described embodiments and a display panel displaying an image by receiving light from the light emission device.

According to an embodiment, a light emission device can reduce or minimize generation of errors during a manufacturing process while suppressing unnecessary electrification with an improved structure.

Further, a display device can include the light emission device.

### BRIEF DESCRIPTION OF THE DRAWINGS

FIG. 1 is a partial cut perspective view of a light emission device according to a first embodiment;

FIG. 2 is a plan view of a first substrate of FIG. 1;

FIG. 3 is a partial cross-sectional view of a light emission device of FIG. 1;

FIG. 4 is a plan view of a first substrate of a light emission device according to a second embodiment;

FIG. 5 is an exploded perspective view of a display device including a light emission device of FIG. 1; and

FIG. 6 is a partial cross-sectional view of a display panel of FIG. 5.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Like reference numerals designate like elements throughout the specification.

Further, sizes and thicknesses of constituent members shown in the accompanying drawings are given for better understanding and ease of description, but the present invention is not limited to the illustrated sizes and thicknesses.

In the drawings, the thickness of layers, films, panels, regions, etc., may be exaggerated for clarity. It will be understood that when an element such as a layer, film, region, or substrate is referred to as being “on” another element, it can be directly on the other element or be indirectly on the other element with one or more intervening elements interposed therebetween. In contrast, when an element is referred to as being “directly on” an other element, there are no intervening elements present interposed therebetween.

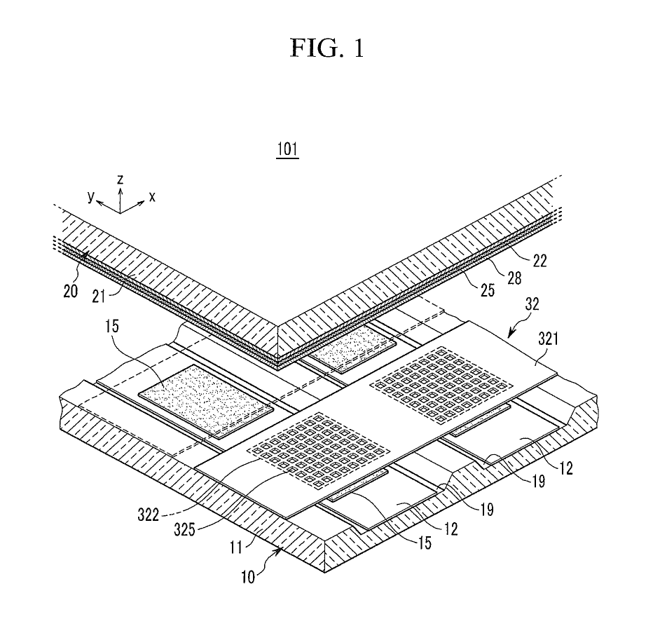

Hereinafter, referring to FIGS. 1 to 3, a light emission device 101 according to a first embodiment is described below.

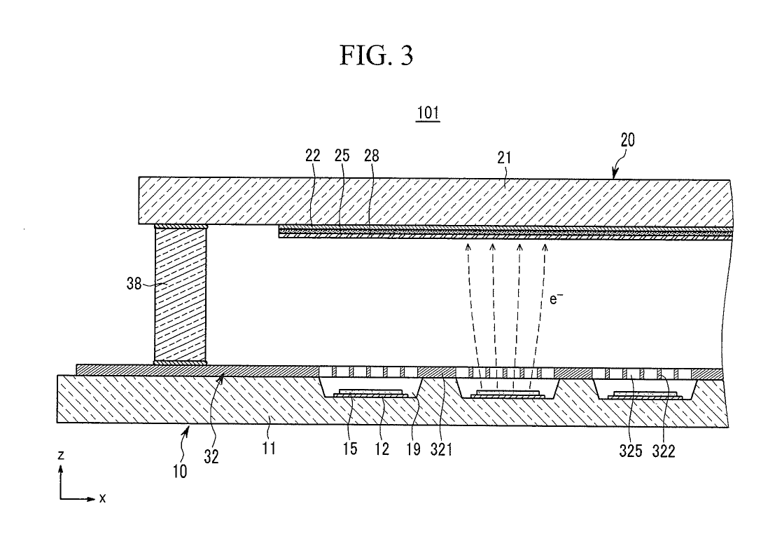

As shown in FIG. 1, the light emission device 101 according to the first embodiment includes a first substrate assembly 10, a second substrate assembly 20 facing the first substrate assembly 10, and a sealing member 38 (shown in FIG. 3) that is disposed at edges of the first substrate assembly 10 and the second substrate assembly 20 to bond and seal the two substrate assemblies 10 and 20 to each other. The inner space formed by the first substrate assembly 10, the second substrate assembly 20, and the sealing member 38 is evacuated to be in a vacuum state maintaining a vacuum degree of about 10⁻⁶ Torr.

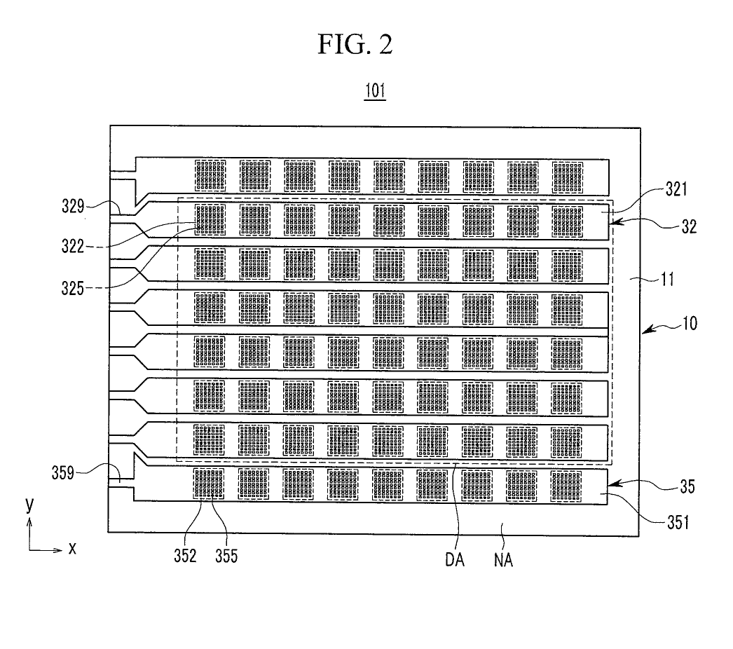

The first substrate assembly 10 includes a substrate or substrate body (hereinafter, referred to as “first substrate body 11”), a first electrode 12, an electron emission unit (electron emission region) 15, a second electrode 32, and an anti-conduction electrode 35 (shown in FIG. 2). Herein, the first electrode 12 is a cathode electrode and the second electrode 32 is a gate electrode. However, the first embodiment is not limited thereto. For example, the first electrode 12 may be the gate electrode, and the second electrode 32 may be the cathode electrode in some cases.

The first substrate body 11 includes one or more concave portions (recess portions or grooves) 19 recessed into the first substrate body 11 in a stripe pattern. The concave portion 19 is formed by removing a part of the first substrate body 11 by a method such as etching and/or sand blasting. In FIGS. 1 and 3, the concave portion 19 of the first substrate body 11 has an inclined side wall, but the present invention is not limited thereto. For example, the concave portion 19 of the first substrate body 11 may have a vertical side wall.

In one embodiment, the first substrate body 11 has a thickness of about 1.8 mm. Further, the concave portion 19 may have a depth of about 40 pm and a width of 300 to 600 pm.

In one embodiment, the first electrode 12 is disposed on the bottom of the concave portion 19 of the first substrate body 11. Here, the first electrode 12 is formed in the stripe pattern to extend along a direction (y-axis direction) parallel to the extension direction of the concave portion 19. That is, the length direction (y-axis direction) of the first electrode 12 is the same as the length direction (y-axis direction) of the concave portion 19. In addition, portions of the first substrate body 11 among the concave portions 19 serve as partitions for separating the adjacent first electrodes 12 from each other.

In one embodiment, the second electrode 32 is formed in the stripe pattern to extend in a direction (x-axis direction) crossing the first electrodes 12, and is formed just above the front surface of the first substrate body 11. Therefore, the second electrode 32 is separated from the first electrode 12 disposed in the concave portion 19 of the first substrate body 11 by approximately the depth of the concave portion 19.

In one embodiment, the electron emission unit 15 is formed just above the first electrode 12 to be spaced from the second electrode 32. In FIG. 1, as an example, the electron emission unit 15 is formed only at (or in) a region where the first electrode 12 and the second electrode 12 cross each other, but the present invention is not limited thereto. For example, the electron emission unit 15 may be formed on the first electrode 12 in the stripe pattern parallel to the first electrode 12.

The electron emission unit 15 contains materials that emit electrons by being applied with an electric field in a vacuum state, i.e., a carbon-based material and/or a nanometer-sized material. The electron emission unit 15 may contain, for example, carbon nanotubes, graphite, graphite nanofibers, diamond, diamond-like carbon, fullerene (C₆₀), silicon nanowire, and combinations thereof.

The electron emission unit 15 may be constituted by an electron emission layer having a set or predetermined thickness through thick-film processing such as screen printing. That is, the electron emission unit 15 may be formed by processes of screen-printing a paste mixture containing an electron emission material on the first electrode 12, drying and sintering the printed mixture, and activating the surface of the electron emission unit 15 so as to expose the electron emission materials to the surface of the electron emission unit 15. The surface activation process can be made by attaching an adhesive tape and then detaching the same. The electron emission materials such as carbon nanotubes can be substantially vertically erected with respect to the surface of the emission electron unit 15 while removing a part of the surface of the electron emission unit 15 through the surface activation process.

As shown in FIG. 2, the anti-conduction electrode 35 is disposed at (and/or along) an edge (or edge portion) of the first substrate body 11 to extend in parallel to the second electrode 32. The first substrate body 11 of the first substrate assembly 10 is divided into a light emission area (DA) corresponding to where the electron emission unit 15 substantially emits electrons and a non-emission area (NA) adjacent to the light emission area (DA). That is, the second electrode 32 is disposed in the light emission area (DA) of the first substrate body 11, and the anti-conduction electrode 35 is disposed in the non-emission area (NA) of the first substrate body 11. The anti-conduction electrode 35 is grounded to suppress any unnecessary charging in a sealed space inside of the light emission device 101.

Further, the second electrode 32 and the anti-conduction electrode 35 each includes mesh units 322 and 352 having opening portions 325 and 355 and support units 321 and 351 that are joined to the first substrate body 11 while surrounding the mesh units 322 and 352.

As shown in FIG. 3, in the first embodiment, the mesh unit 322 of the second electrode 32 is formed on the electron emission unit 15 at (or) in a region crossing the first electrode 12. That is, electrons emitted from the electron emission unit 15 go toward the second substrate 20 by passing through the mesh unit 322 of the second electrode 32. Therefore, the mesh unit 322 of the second electrode 32 serves to focus the passing electrons. Further, since the mesh unit 322 of the second electrode 32 is formed in only the region crossing the first electrode 12, it is possible to reduce or prevent a voltage drop of the second electrode 32 while the second electrode 32 is being driven by reducing line resistance of the second electrode 32.

The support unit 321 of the second electrode 32 is in direct contact with the front surface of the first substrate body 11, and is joined to the first substrate body 11 through the sealing member 38 disposed at the edge (or edge portion) of the first substrate body 11 or an additional adhesive member. In addition, the support unit 351 of the anti-conduction electrode 35 is also joined to the first substrate body 11 like the support unit 321 of the second electrode 32.

Further, as shown in FIG. 2, the anti-conduction electrode 35 includes the mesh unit 352 and the support unit 351 that are formed with substantially the same pattern as the second electrode 32. Herein, the substantially same pattern refers to that since the width of the anti-conduction electrode 35 is slightly different from that of the second electrode 32, the mesh units 322 and 352 that are formed in the anti-conduction electrode 35 and the second electrode 32, respectively, may be slightly different from each other.

However, the first embodiment is not limited thereto. For example, the mesh unit 352 of the anti-conduction electrode 35 may be formed in regions not crossing the first electrode 12 in addition to the region crossing the first electrode 12, unlike the mesh unit 322 of the second electrode 32. That is, the mesh unit 352 of the anti-conduction electrode 35 may not be intermittently formed but may be continuously formed through every crossing region.

Further, the anti-conduction electrode 35 may not cross the first electrode 12. That is, the first electrode 12 and the electron emission unit 15 may not be disposed below the anti-conduction electrode 35.

Further, the second electrode 32 and the anti-conduction electrode 35 are each made of a metal plate having a thickness larger than that of the first electrode 12. For example, the second electrode 32 and the anti-conduction electrode 35 may be manufactured through a step of forming the opening portion 325 by cutting the metal plate in a stripe pattern and removing a part of the metal plate by using a method such as etching.

The second electrode 32 and the anti-conduction electrode 35 may be made of a nickel-iron alloy and/or a metallic material other than the alloy, and may be formed to have a thickness of about 50 pm and a width of 10 mm. After the second electrode 32 and the anti-conduction electrode 35 are manufactured by a process that is different than that of the first electrode 12 and the electron emission unit 15, the second electrode 32 and the anti-conduction electrode 35 are fixed onto the top of the first substrate body 11 to extend in the direction crossing the first electrode 12. Here, since the first electrode 12 and the electron emission unit 15 are positioned in the concave portion 19 of the first substrate body 11, it is possible to naturally (or automatically) achieve insulation between the first electrode 12 and the second electrode 32 by only fixing the second electrode 32 onto the top of the first substrate body 11.

As such, the anti-conduction electrode 35 is made of the same material as the second electrode 32 and disposed on the first substrate member 11 through the same process. Further, the anti-conduction electrode 35 has the same or substantially the same structure as the second electrode 32. Therefore, in the case where the second electrode 32 is thermally deformed during a manufacturing process, the anti-conduction electrode 35 is also thermally deformed in a substantially similar manner to that of the second electrode 32. That is, any difference in a thermal deformation amount between the second electrode 32 and the anti-conduction electrode 35 is negligible. Therefore, it is possible to suppress generation of an error due to the difference in the thermal deformation amount between the anti-conduction electrode 35 and the second electrode 32. For example, if the anti-conduction electrode 35 does not include the mesh unit 352, the anti-conduction electrode 35 shows a large difference in the thermal deformation amount in comparison with the second electrode 32. In addition, the second electrode 32 may be twisted to cause various errors such as a light emission error or a vacuum state error due to the difference in the thermal deformation between the anti-conduction electrode 35 and the second electrode 32.

Further, since the anti-conduction electrode 35 is formed at the time when the second electrode 32 is formed, a process for adding an additional component such as a separately formed anti-conduction film may be omitted. That is, it is possible to simplify the manufacturing process.

Also, as shown in FIG. 3, the concave portion 19 of the first substrate body 11 has a width larger than that of the first electrode 12, and has a recession depth larger than that of the sum of the thickness of the first electrode 12 and the thickness of the electron emission unit 15. Therefore, the second electrode 32 is stably separated from the first electrode 12 disposed in the concave portion 19 of the first substrate body 11. That is, the first electrode 12 and the second electrode 32 are stably insulated from each other.

Further, one crossing region between the first electrode 12 and the second electrode 32 may correspond to (or be positioned at) one pixel area of the light emission device 101, or two or more crossing regions may correspond to (or be positioned at) one pixel area of the light emission device 101. In the latter case, the first electrodes 12 or the second electrodes 32 corresponding to one pixel area are electrically connected to each other to be applied with the same voltage.

Further, the anti-conduction electrode 35 may be formed on the concave portion 19 of the first substrate body 11 or not formed thereon. Therefore, since the anti-conduction electrode 35 is not a driving electrode, the anti-conduction electrode 35 may be arbitrarily disposed regardless of the concave portion 19, the first electrode 12, and the electron emission unit 15 of the first substrate body 11.

In one embodiment, the second substrate assembly 20 includes a substrate or substrate body (hereinafter, referred to as “second substrate body 21”), a third electrode 22, a phosphor layer (or a fluorescent layer) 25, and a reflection film 28. The third electrode 22, the phosphor layer 25, and the reflection film 28 are sequentially formed on an inner surface of the second substrate body 21 facing the first substrate assembly 10. That is, the third electrode 22, the phosphor layer 25, and the reflection film 28 are sequentially arranged adjacent to the second substrate body 21. Herein, the third electrode 22 is the anode electrode. In addition, the first substrate body 11 and the second substrate body 21 may be made of a ceramic-based material such as glass, for example.

The third electrode 22 is made of a transparent conductive material such as indium tin oxide (ITO) so as to transmit visible light emitted from the phosphor layer 25. The third electrode 22 functions as an acceleration electrode for inducing the electrons, and maintains the phosphor layer 25 in a high-voltage state by being applied with a positive direct-current voltage (hereinafter, referred to as “anode voltage”) of thousands of volts.

The phosphor layer 25 may be formed of a mixed phosphor and/or fluorescent material that emits white light by mixing a red phosphor and/or fluorescent material, a green phosphor and/or fluorescent material, and a blue phosphor and/or fluorescent material with each other. In FIGS. 1 and 2, the phosphor layer 25 is formed in the entire light emission area of the second substrate body 21, but the present invention is not limited thereto. For example, the phosphor layer 25 may be separately formed in each pixel area.

The reflection film 28 may be composed of an aluminum thin film having a thickness of thousands of angstroms (A), and formed with minute holes for passing the electrons. The reflection film 28 reflects the visible light emitted toward the first substrate 10 among visible light emitted from the phosphor layer 25 to increase the luminance of the light emission device 101.

In addition, the third electrode 22 or the reflection film 28 may be omitted. In the case where the third electrode 22 is omitted, the reflection film 28 can perform the same function as the third electrode 22 by being applied with the anode voltage.

By this configuration, in pixels where a voltage difference between the first electrode 12 and the second electrode 32 is equal to or larger than a threshold value, an electric field is formed around the electron emission unit 15, thereby emitting electrons. The emitted electrons collide with a corresponding portion of the phosphor layer 25 by being induced by the anode voltage applied to the third electrode 22 so as to allow the corresponding phosphor layer to emit the light. The luminance of the phosphor layer 25 for each pixel corresponds to the emission quantity of electron beams of the corresponding pixel.

Since the mesh unit 322 of the second electrode 32 is disposed just on the electron emission unit 15, electrons emitted from the electron emission unit 15 pass through the opening portion 325 of the mesh unit 322 in the state of reduced or minimized beam dispersion and reach the phosphor layer 25. Accordingly, the light emission device 101 according to the first embodiment can effectively protect or prevent a side wall of the concave portion 19 from being charged with electric charges by reducing an initial dispersion angle of the emitted electrons.

As a result, the light emission device 101 according to the first embodiment can stabilize driving by improving withstand voltage characteristics of the first electrode 12 and the second electrode 32 and implement high luminance by applying a high voltage of 10 kV or more, and, in one embodiment, a high voltage of 10 to 15 kV, to the third electrode 22.

Further, in the case of the light emission device 101 according to the first embodiment, since the thick-film processing for forming the insulating layer and the thin-film processing for forming the second electrode 32 are not needed, it is possible to simplify the manufacturing process.

Further, since the second electrode 32 is disposed after forming the electron emission unit 15, it is possible to protect or prevent the first electrode 12 and the second electrode 32 from being short-circuited due to a conductive electron emission material during the formation of the electron emission unit 15.

By the above-mentioned configuration, the light emission device 101 can reduce or minimize the generation of errors during a manufacturing process while suppressing unnecessary electrification.

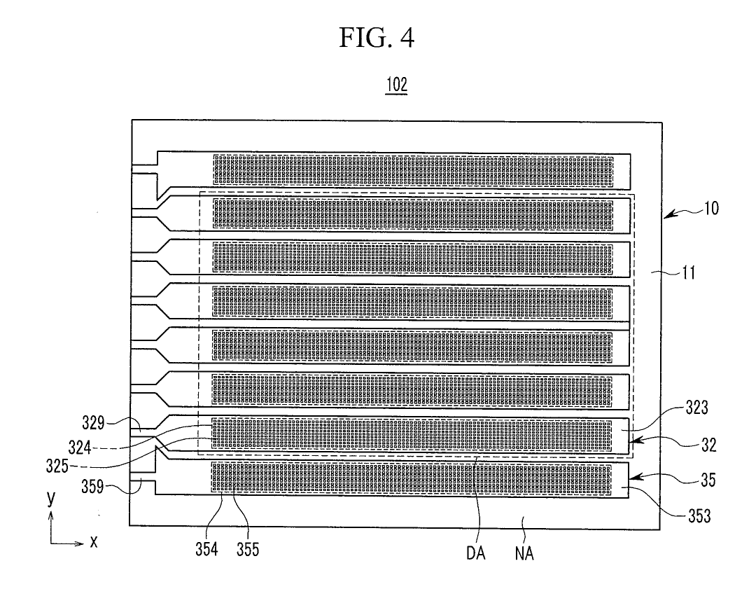

Hereinafter, referring to FIG. 4, a light emission device 102 according to a second embodiment is described below in more detail.

As shown in FIG. 4, in the second embodiment, the mesh unit 324 of the second electrode 32 is formed on the electron emission unit 15 in the region crossing the first electrode 12 in addition to the regions not crossing the first electrode 12, in the light emission device 102. That is, the mesh unit 324 of the second electrode 32 is formed in the region crossing the first electrode 12 and between the regions crossing the first electrode 12.

Therefore, an area occupied by the support unit 323 of the second electrode 32 is relatively reduced. In addition, a part of the mesh unit 324 of the second electrode 32 is also in direct contact with the front surface of the first substrate body 11.

Further, the mesh unit 354 and the support unit 353 of the anti-conduction electrode 35 are also formed with the substantially same pattern as the second electrode 32.

Here, in the second embodiment, when the mesh unit 324 of the second electrode 32 is formed, a process of arranging the second electrodes 32 can be more easily performed (e.g., be performed without a complicated alignment process). Accordingly, since an arrangement of the second electrode 32 is simplified at the time of disposing the second electrode 32, productivity can be improved.

By the above-mentioned configuration, the light emission device 102 can reduce or minimize generation of errors during a manufacturing process while suppressing unnecessary electrification and manufacturing productivity can be improved.

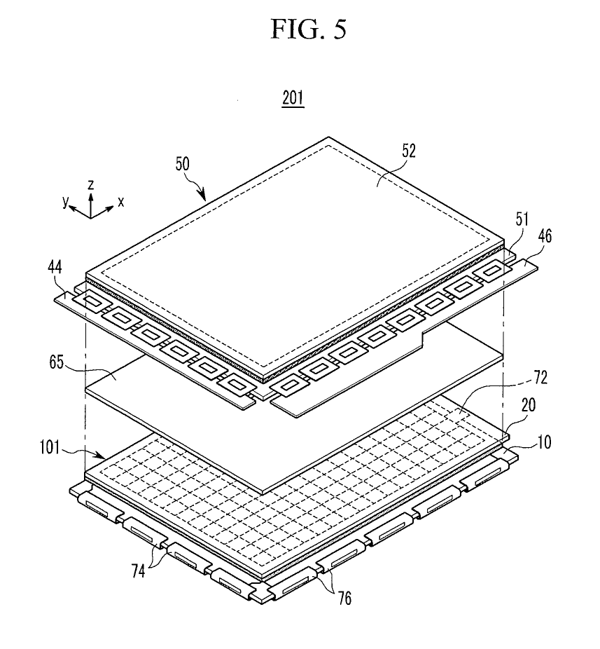

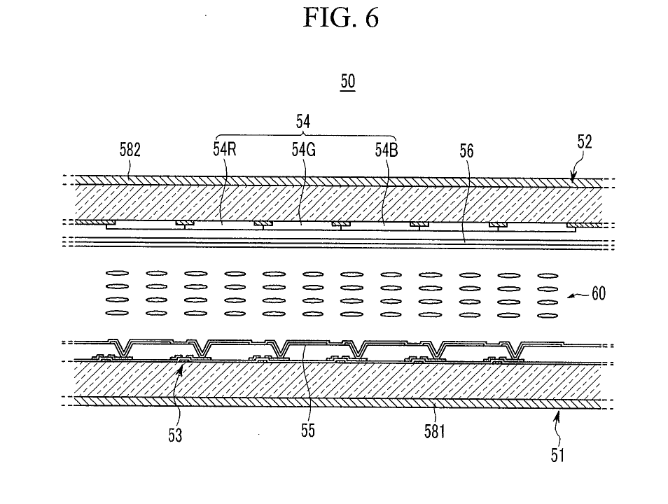

Hereinafter, referring to FIGS. 5 and 6, a display device 201 according to an embodiment is described below. A display device 201 according to the embodiment may include light emission devices 101 and 102 according to the above-mentioned various embodiments. Hereinafter, the display device 201 with the light emission device 101 of FIG. 1 is described below as an example.

As shown in FIG. 5, the display device 201 includes the light emission device 101 and a display panel 50 disposed in the front of the light emission device 101. Here, the display device 201 may (or may not) include a diffusion member 65 that is disposed between the light emission device 101 and the display panel 50 to evenly diffuse light emitted from the light emission device 101. The diffusion member 65 and the light emission device 101 are spaced from each other by a set or predetermined distance. The display device 201 includes the light emission device 101 according to the first embodiment as a light source.

In FIGS. 5 and 6, a liquid crystal display panel is used as the display panel 50, but the present invention is not limited thereto. For example, the display panel 50 may be a non-emissive display panel other than the liquid crystal display panel.

As shown in FIG. 6, the display panel 50 includes a first display plate 51 where a thin film transistor (TFT) 53 and a pixel electrode 55 are formed, a second display plate 52 where a color filter layer 54 and a common electrode 56 are formed, and a liquid crystal layer 60 injected between the first display plate 51 and the second display plate 52. Polarizing plates 581 and 582 are attached to a front surface of the display plate 51 and a rear surface of the second display plate 52 to polarize light passing through the display panel 50.

The pixel electrode 55 is positioned in each sub-pixel. Driving the pixel electrode 55 is controlled by the thin film transistor 53. Herein, a plurality of sub-pixels (e.g., three sub-pixels) implementing different colors are grouped together to constitute one pixel. The pixel is a minimum unit for displaying an image. The pixel electrode 55 and the common electrode 56 are made of a transparent conductive material. The color filter layer 54 includes a red filter layer 54R, a green filter layer 54G, and a blue filter layer 54B that are positioned in the sub-pixels, respectively.

When the thin film transistor 53 of a certain sub-pixel is turned on, an electric field is formed between the pixel electrode 55 and the common electrode 56. Array angles of liquid crystal molecules of the liquid crystal layer 60 are changed by the electric field. Light permeability is changed according to the changed array angles of the liquid crystal molecules. The display panel 50 can display the image by controlling luminance and illumination color for each pixel through the process.

Further, the display panel 50 is not limited to the above-mentioned structure, and may be modified in various suitable configurations.

In addition, as shown in FIG. 6, the display device 201 includes a gate circuit substrate 44 supplying a gate driving signal to a gate electrode of each thin film transistor 53 of the display panel 50, and a data circuit substrate 46 supplying a data driving signal to a source electrode of each thin film transistor 53 of the display panel 50.

The light emission device 101 allows one pixel of the light emission device 101 to correspond to two or more pixels of the display panel 50 and is formed to have fewer pixels than that of the display panel 50.

Each pixel of the light emission device 101 can emit light in correspondence with the gray levels of the pixels of the display panel 50 corresponding thereto. For example, each pixel of the light emission device 101 can emit light in correspondence with the highest gray level among the gray levels of the pixels of the display panel 50. Each pixel of the light emission device 101 can display gray levels in a gray-scale of 2 to 8 bits.

Hereinafter, for convenience of description, a pixel of the display panel 50 is referred to as a first pixel, a pixel of the light emission device 101 is referred to as a second pixel, and multiple first pixels corresponding to one second pixel are referred to as a first pixel group.

A driving process of the light emission device 101 may include a step of allowing a signal controller for controlling the display panel 50 to detect the highest gray level among the gray levels of the first pixels of the first pixel group, a step of calculating a gray level required for emitting the second pixel in accordance with the detected gray level and converting the calculated gray level into digital data, a step of generating a driving signal of the light emission device 101 by using the digital data, and a step of applying the generated driving signal to a driving electrode of the light emission device 101.

The driving signal of the light emission device 101 is constituted by a scanning signal and a data signal. Either the first electrode 12 or the second electrode 32 is applied with the scanning signal and the other electrode is applied with the data signal.

Further, a data circuit substrate and a scanning circuit substrate for driving the light emission device 101 may be disposed on a rear surface of the light emission device 101. The data circuit substrate and the scanning circuit substrate are connected to the first electrode 12 and the second electrode 32 through a first connector 76 and a second connector 74, respectively. In addition, a third connector 72 applies the anode voltage to the third electrode 22.

As described above, the second pixel of the light emission device 101 is synchronized with the first pixel group to emit light at a certain or predetermined gray level when the image is displayed in the corresponding first pixel group. That is, the light emission device 101 provides light having high luminance to a bright region in a screen implemented by the display panel 50 and provides light having low luminance to a dark region of the screen. Therefore, the display device 201 according to the embodiment can increase a contrast ratio of the screen and implement clearer image quality.

By the above-mentioned configuration, the display device 201 can reduce or minimize generation of errors during the manufacturing process while suppressing generation of unnecessary electrification in the light emission device 101.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A light emission device, comprising:
a substrate body having a concave portion recessed into the substrate body and extending along a first direction;
a first electrode in the concave portion and extending along the first direction;
a second electrode on a front surface of the substrate body and extending along a second direction crossing the first electrode;
an anti-conduction electrode disposed at an edge portion of the substrate body and extending along the second direction to be parallel with the second electrode; and
an electron emission unit on the first electrode and spaced apart from the second electrode,
wherein each of the second electrode and the anti-conduction electrode comprises:
a mesh unit having a plurality of opening portions; and
a support unit joined to the substrate body while surrounding the mesh unit.

2. The light emission device of claim 1, wherein
the substrate body is divided into a light emission area corresponding to where the electron emission unit emits electrons and a non-emission area adjacent to the light emission area,
the second electrode is disposed in the light emission area of the substrate body, and
the anti-conduction electrode is disposed in the non-emission area of the substrate body.

3. The light emission device of claim 2, wherein
the anti-conduction electrode is grounded.

4. The light emission device of claim 2, wherein
each of the second electrode and the anti-conduction electrode has a thickness larger than that of the first electrode, and is formed of a metal plate composed of identical material.

5. The light emission device of claim 1, wherein
the mesh unit of the second electrode is formed only at a region of the second electrode crossing the first electrode.

6. The light emission device of claim 1, wherein
the mesh unit of the second electrode is formed both at a region of the second electrode crossing the first electrode and a region of the second electrode between the region of the second electrode crossing the first electrode, and another region of the second electrode crossing another first electrode.

7. The light emission device of claim 1, wherein
the mesh unit of the anti-conduction electrode is formed with an identical pattern as the mesh unit of the second electrode.

8. The light emission device of claim 1, wherein
the concave portion has a width larger than that of the first electrode, and
the concave portion has a recession depth larger than a sum of a thickness of the first electrode and a thickness of the electron emission unit.

9. The light emission device of claim 1, further comprising:
an additional substrate body facing the substrate body; and
a third electrode and a phosphor layer on a surface of the additional substrate body facing the substrate body.
